(19) United States
(12) Patent Application Publication
(10) Pub. No.: US 2012/0056199 A1
(43) Pub. Date: Mar. 8, 2012

(54) Self-supporting CVD diamond film and method for producing a self-supporting CVD diamond film

(75) Inventors: Stefan Rosiwal, Bamberg (DE); Jan Fandrey, Erlangen (DE); Karsten Kellermann, Altdorf (DE); Matthias Lodes, Erlangen (DE)

(73) Assignee: Friedrich-Alexander-Universitaet Erlangen-Nuernberg, Schlossplatz 4 (DE)

(21) Appl. No.: 13/138,552

(22) PCT Filed: Mar. 5, 2010
(86) PCT No.: PCT/EP2010/052840

§ 371 Date: Oct. 28, 2011

(30) Foreign Application Priority Data
Mar. 6, 2009 (EP) 09 154 542.6

(51) Int. Cl. H01L 29/16; H01L 21/20

(52) U.S. Cl. 257/77; 438/478; 257/E29.082; 257/E21.09

(57) ABSTRACT

The invention relates to a self-supporting CVD diamond film comprising a plurality of diamond layers (8) lying one over the other, wherein a lower side of each diamond layer (8) is made of diamond having a first average crystal size of 2 to 50 nm, wherein the average crystal size increases within the diamond layer (8) from the lower side to an upper side of the diamond layer (8), and wherein a second average crystal size in the area of the upper side is 50 to 500 nm.

The invention relates to a self-supporting CVD diamond film. It further relates to a method for producing a self-supporting CVD diamond film.

EP 0 666 338 B1 discloses a method for producing a self-supporting CVD diamond film. Potential-convex diamond layers with a potential of a convex deformation and potential-concave diamond layers with a potential of a concave deformation are thereby successively deposited alternately by means of a CVD method. Due to the alternating arrangements of the potential-convex and the potential-concave layers, internal stresses are compensated, which can cause a deformation of the self-supporting diamond layer. The self-supporting diamond film produced in this manner is essentially even.

EP 0 574 263 A1 discloses a diamond film produced by means of a CVD method. In the production of the diamond film the conditions are selected such that an average crystal sixe inside the uniformly embodied diamond layer is no larger than 1 μm. An undesirable bending of a self-supporting diamond film can also be avoided therewith.

EP 0 561 588 A1 discloses a diamond film produced from several diamond layers by CVD method, in which nuclei made of metal are incorporated between the diamond layers. Nothing is said in this document about an average crystal size of the diamond crystals forming the diamond layers.

Only relatively small self-supporting CVD diamond films or diamond films, respectively, can be produced with the known methods in practice. Large-area diamond films, for example, with a diameter of more than 10 cm, usually have undesirable curvatures and/or break easily.

The object of the invention is to eliminate the disadvantages according to the prior art. In particular, a method is to be disclosed that can be carried out as easily and cost-effectively as possible, which renders possible the production of large-area, robust, self-supporting CVD diamond films. According to a further object of the invention, a large-area CVD diamond film that is robust in handling is to be disclosed.

This object is attained by the features of claims 1, 10 and 13. Expedient embodiments of the invention result from the features of claims 2 through 9, 11 and 12 as well as 14 through 24.

According to the invention, a self-supporting diamond film is proposed, comprising a plurality of diamond layers stacked one on top of the other,

wherein an underside of each diamond layer is formed of diamond with a first average crystal size of 2 to 50 nm,
wherein the average crystal size inside the diamond layer increases from the underside to the top side of the diamond layer, and
wherein a second average crystal size in the region of the top side is 50 to 500 nm.

The proposed self-supporting CVD diamond film is composed of a plurality of diamond layers stacked one on top of the other. Each of the diamond layers is graded, i.e., an average crystal size of the diamond crystals forming the diamond layer increases from an underside of the diamond layer to the top side thereof. A first average crystal size in the region of the underside is thereby 2 to 50 nm and a second average crystal size in the region of the top side of the diamond layer is 50 to 500 nm. On the top side of a diamond layer a further underside of the next following diamond layer is stacked. No heterogeneous nuclei, for example, metal nuclei or the like are incorporated between the top side and the further underside of the next following diamond layer. This opens up the possibility of also using the proposed self-supporting CVD diamond film to produce semiconductors.

The proposed self-supporting CVD diamond film is surprisingly extremely robust. Disks with a diameter of more than 10 cm can be produced. The produced disks or diamond films are characterized by an excellent flatness.

According to an advantageous embodiment, the first average crystal size is 2 to 30 nm, preferably 5 to 20 nm. The second average crystal size is expediently no more than 200 nm. Furthermore, it has proven to be expedient that the diamond layer has a layer thickness in the range of 10 nm to 5 μm, preferably in the range of 100 nm to 2 μm. A self-supporting CVD diamond film formed from the above-referenced diamond layers is particularly robust. It can be produced in a size of more than 100 cm².

Furthermore it has proven to be expedient that a total layer thickness of the self-supporting CVD diamond film is in the range of 20 μm to 200 μm, preferably 40 μm to 100 μm. Self-supporting CVD diamond layers of the proposed total layer thickness are so mechanically stable that they can be handled well.

According to a further advantageous embodiment, an outside of the self-supporting CVD diamond film has a maximum peak-to-valley height R_{z} of 0.01 μm to 4.0 μm. Because the self-supporting CVD diamond film has a particularly smooth surface on at least one of its outsides, the resistance thereof to breakage is increased. The proposed self-supporting CVD diamond film is particularly stable and can be handled well.

The “maximum average peak-to-valley height R_{z}” is understood to mean the maximum roughness profile height as defined by DIN EN ISO 4287. This is the sum of the height of the largest profile peak Rp and the depth of the largest profile valley Rv of the roughness profile within a sampling length.

As the perpendicular distance from the highest to the deepest profile point, R_{z} is a gauge of the scattering range of the roughness ordinate values. R_{z} is determined as the arithmetic average from the maximum profile heights of five sampling lengths lr in the roughness profile.

The proposed self-supporting CVD diamond film is also suitable for the production of semiconductor elements. For this purpose, at least one diamond layer can be provided with an n-doping. The diamond layer provided with the n-doping can contain nitrogen, sulfur or phosphorus as the doping. Furthermore, at least one diamond layer can be provided with a p-doping. The diamond layer provided with the p-doping can contain as boron, hydrogen, indium, aluminum or gallium as the doping.

To produce a p-n transition, a diamond layer provided with the n-doping and a diamond layer provided with the p-doping can be deposited one on top of the other. According to a particularly advantageous embodiment, a diamond layer can contain 100 ppm to 20,000 ppm, preferably 500 ppm to 2,000 ppm boron.

According to a further embodiment, it can also be provided that the self-supporting CVD diamond layer in all is only n-conducting or p-conducting. That is, in this case all of the diamond layers can be provided with an n-doping or a p-doping.

The self-supporting CVD diamond film according to the invention can be coated on at least one of its two sides, preferably by means of sputtering, with a metal layer produced from a metal. The provision of a metal layer of this type renders possible a connection of the self-supporting CVD diamond film by means of welding, in particular electron beam welding, laser welding or the like.

Furthermore, according to the invention a component is proposed, in which a self-supporting CVD diamond film is applied to at least one component surface. The tribological properties of the component in the region of the component surfaces provided with the self-supporting CVD diamond film can thus be improved considerably.

For the application of the diamond film on the surface a connecting layer can be provided. The connecting layer is expediently designed such that thermally induced tensions between the CVD diamond layer and the component are compensated. To this end, the connecting layer can also be embodied in a multi-layer manner. Particularly large differences of the thermal coefficient of expansion of a component compared to the self-supporting diamond film can be compensated in that layers one above the other, for example, are layered with an increasing thermal coefficient of expansion.

The component surface can also be a further outside of a further self-supporting CVD diamond film according to the invention. That is, several self-supporting CVD diamond films according to the invention can be connected to one another, for example, with the interposition of a carbide-forming metal layer or by means of hot pressing. In particular, p-conducting and n-conducting diamond films can be connected to one another. This renders possible the production of thermoelectric components.

According to an advantageous embodiment of the invention, the connecting layer is produced from a first metal. The first metal can be a solder.

The connecting layer can also be made of a polymer, a ceramic or a glass. It has proven to be particularly expedient for the polymer to be a preceramic polymer. A particularly strong connection that is easy to produce can thus be produced between the self-supporting diamond film and a component surface.

Furthermore according to the invention, a method for producing a self-supporting CVD diamond film according to the invention is proposed with the following steps:

Application of diamond nuclei onto the surface of a substrate,
Insertion of the substrate provided with the diamond nuclei into a reaction chamber of a CVD device,
Deposition of a diamond layer by means of a CVD method, wherein during a first dwell time of 1 to 10 hours in the reaction chamber a predetermined first concentration of a carbonaceous gas is adjusted,
wherein to produce a further diamond layer the following steps are carried out in succession:
a) Increase of the concentration of the carbonaceous gas to a predetermined second concentration for a second dwell time of 20 to 600 seconds and
b) Reduction of the concentration of the carbonaceous gas to the predetermined first concentration and maintenance of the first concentration for the first dwell time.

The proposed method for producing further diamond layers can be carried out particularly easily and cost-effectively. It has surprisingly turned out that, by maintaining the parameters suggested in step lit. a), on a relatively coarse crystalline surface of a diamond layer a next following diamond layer can again be produced, which has an underside embodied in a microcrystalline manner. In contrast to the previous level of knowledge, it is not necessary for this purpose to provide foreign nuclei formed of metal, for instance, on the surface of a diamond layer.

The steps lit. a) and b) can be repeated several times. It has proven to be expedient to repeat the steps lit. a) and lit. b) 10 to 50 times, preferably 15 to 30 times so that a self-supporting diamond film has 11 to 50, preferably 16 to 30 diamond layers.

The first dwell time can be 1 to 4 hours. Furthermore, it has proven to be expedient that the first concentration is 2.8 to 4.0%, preferably 3.0 to 3.8%. Methane is thereby expediently used as the carbonaceous gas.

Furthermore, it has proven to be expedient to use as a substrate a substrate of copper, molybdenum, tungsten or silicon, preferably a silicon wafer. Particularly with the use of a silicon wafer it is particularly easy to detach the self-supporting diamond film.

Furthermore, it has proven to be advantageous that a surface of the substrate exposed to the gas atmosphere has a maximum average peak-to-valley height R_{z} in the range of 0.01 to 4.9 μm, preferably 0.1 to 0.5 μm. During the cooling of the substrate the diamond layer deposited thereon can be detached particularly quickly and easily from a surface of this type. The one outside of the self-supporting diamond film facing towards the surface is then embodied particularly smoothly.

The maximum average peak-to-valley height thereof corresponds to the maximum average peak-to-valley height of the surface of the substrate.

According to a further advantageous process step, the self-supporting diamond film can be exposed to a heat treatment at a temperature of at least 500° C. in an oxygen-containing atmosphere. Hydrogen can thus be removed from the surface of the self-supporting diamond film and through the adsorption of oxygen a polar hydrophilic surface can be produced. A surface modified in this manner is particularly suitable for connecting to polar adhesives. The proposed heat treatment moreover contributes to the enlargement of the surface. This in turn supports the mechanical and/or chemical bonding of adhesives.

According to a further embodiment of the method, the self-supporting diamond film is coated on at least one of its two outsides, preferably by means of sputtering, with a metal layer produced from a first metal. A metal layer of this type can be used as an electrode or also as a connecting layer for producing a connection, for example, to a metallic surface of a component. In the “hot wire CVD method”, for example, heating resistors or filaments made of tungsten are heated to temperatures in the range of 1,700° C. to 2,400° C. As a result, a temperature of the substrate during the deposit of the diamond layers is expediently 600° C. to 1,000° C., expediently 800° C. to 900° C. The substrate is thereby in a carbonaceous gas atmosphere, which can contain, for example, methane, hydrogen, oxygen and other gases. Instead of the hot wire CVD method, a microwave CVD method can also be used.

Furthermore, it has proven to be expedient to produce respectively one self-supporting diamond film according to the invention at the same time on a front side and a rear side of the substrate. The efficiency of the proposed method can thus be doubled.

Embodiments of the invention are described in more detail below based on the drawings. They show:

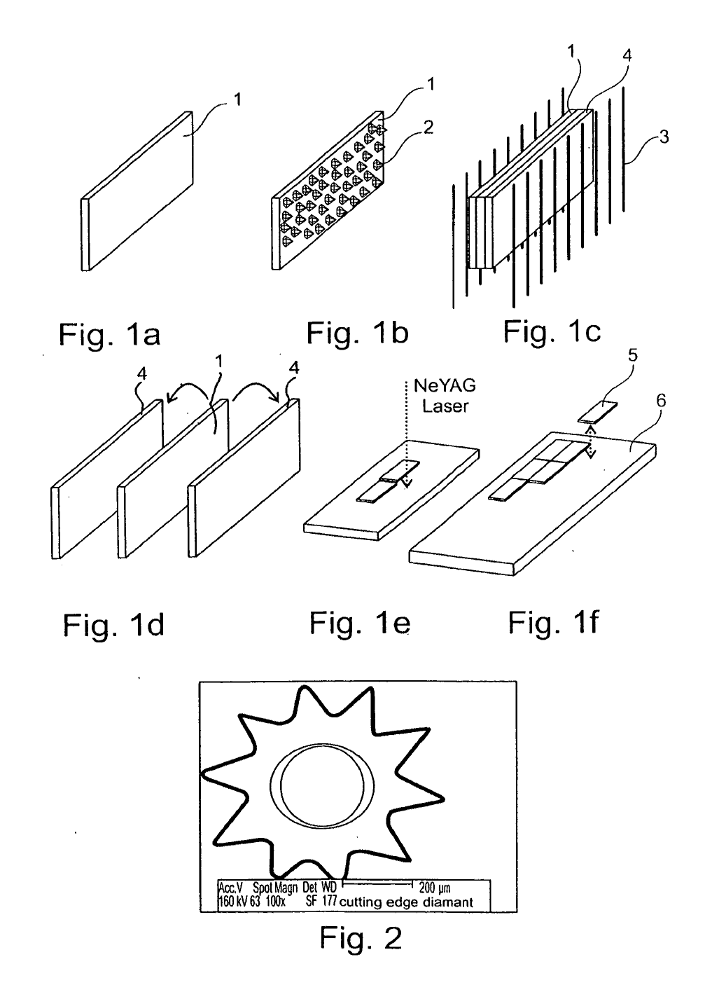

FIGS. 1a-f The production of a self-supporting diamond film as well as a component coated therewith,

FIG. 2 a self-supporting diamond film with a predetermined shape,

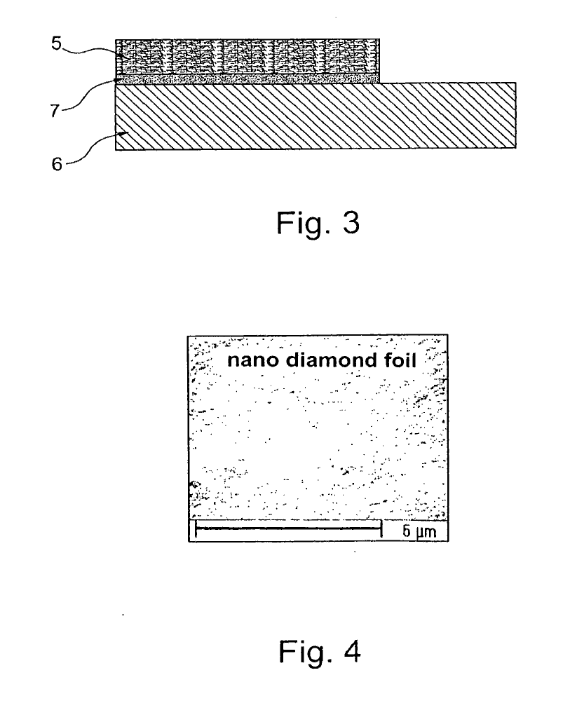

FIG. 3 a diagrammatic sectional view through a component coated with a self-supporting diamond film,

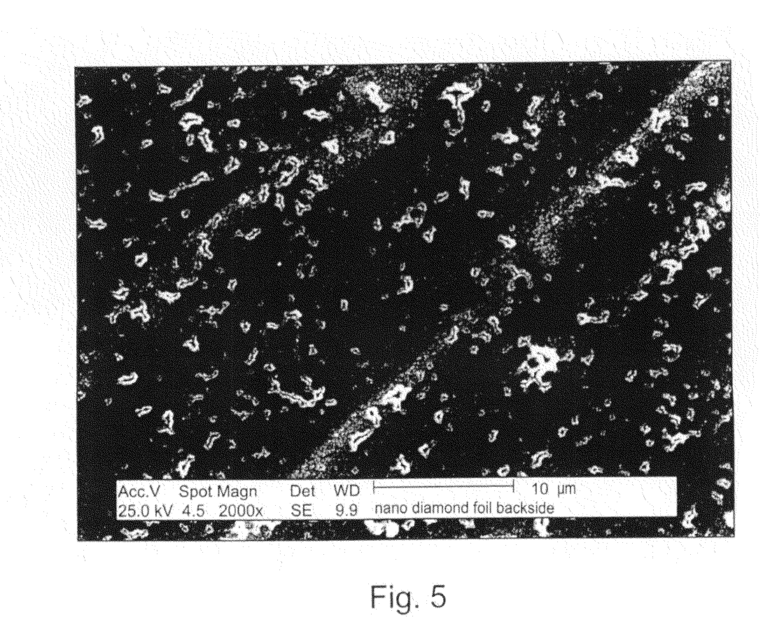

FIG. 4 an electron microscope image of a surface of a self-supporting diamond film,

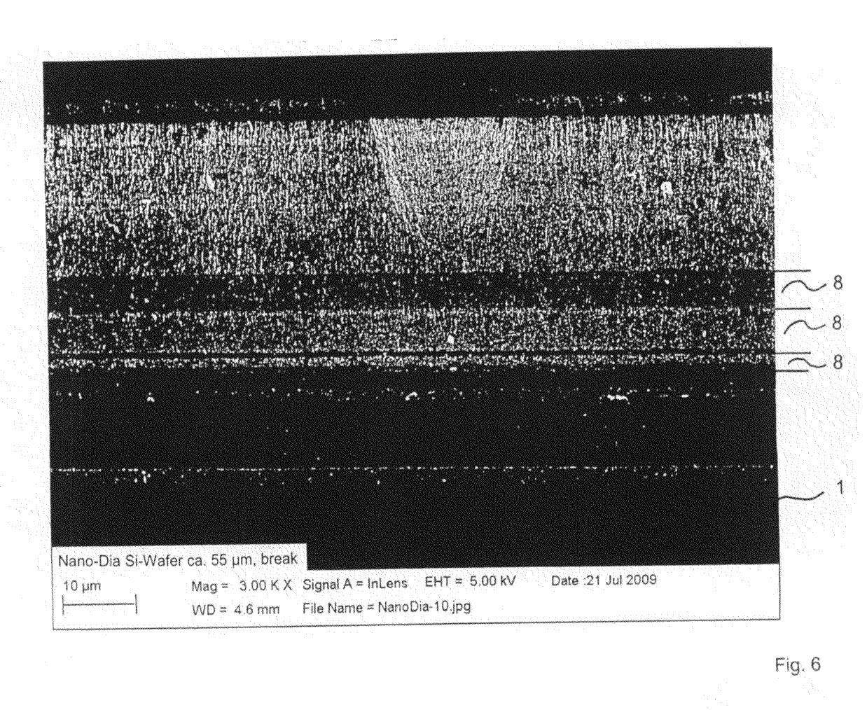

FIG. 5 an electron microscope image of an underside of a self-supporting diamond film,

FIG. 6 an electron microscope image of the layer structure of the self-supporting diamond film,

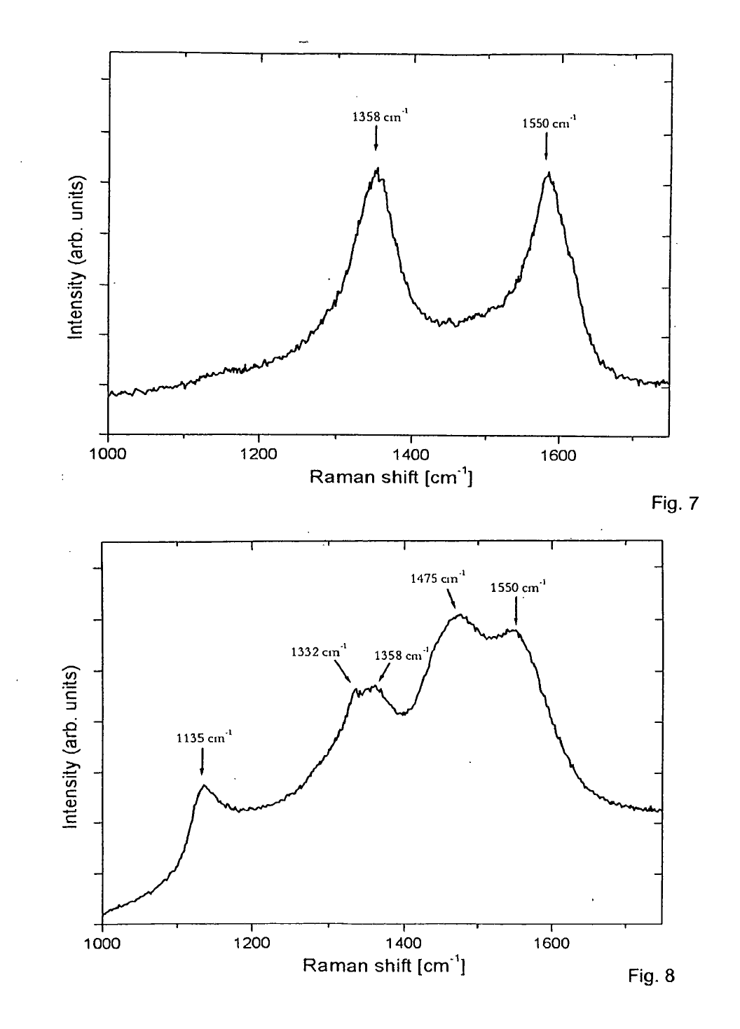

FIG. 7 a Raman spectrum of an underside of a diamond layer and

FIG. 8 a Raman spectrum of a top side of a diamond layer.

FIGS. 1a through d show diagrammatically the production of a self-supporting diamond film. Firstly a substrate 1 made of metallic copper or a copper alloy or a silicon wafer is provided (FIG. 1a). The substrate 1 has an average peak-to-valley height R_{z} of, for example, 0.2 μm at least on its two large surfaces. An average peak-to-valley height R_{z} of this type can be produced by means of conventional grinding, lapping and polishing methods.

The surface of the substrate 1 is subsequently covered in a conventional manner in the ultrasonic bath with diamond nuclei 2, which have an average crystal size in the range of a few nanometers (see FIG. 1b). The application of diamond nuclei 2 onto the surface of the substrate 1 can also be carried out in a CVD reaction chamber by means of ion acceleration onto the substrate surface, for example by means of “biasing”The substrate 1 used for depositing the diamond layer does not need to be an even substrate 1. The substrate 1 can also have a non-even three-dimensional shape, which renders possible a detaching of a self-supporting CVD diamond film 4 deposited thereon. In this manner, for example, conically shaped rings, self-supporting diamond films 4 with projections which can act as stacking aids, and the like can be produced.

The substrate 1 coated with diamond nuclei 2, e.g., the silicon wafer, is placed in the CVD reactor (not shown here) such that the hot wires 3 thereof run approximately parallel to the sides of the substrate 1 to be coated (see FIG. 1c). The hot wires 3 are preferably made from W-WC. In the CVD reactor an atmosphere essentially containing methane and hydrogen is then adjusted. A first concentration of methane is thereby 3.0 to 4.3%, preferably 3.4 to 4.0%. The heating resistors 3 are heated to a temperature of 2,000° C. to 2,400° C. As a result in each case a diamond layer 8 is deposited from the carbonaceous atmosphere to be found in the CVD reactor onto both surfaces of the substrate 1. With the hot wire CVD method, the parameters are preferably chosen such that an average crystal size of the diamond crystals forming the diamond layer 8 increases from 2 to 30 nm on the underside and up to 100 to 200 nm on the top side. The temperature of the substrate 1 during the coating is approximately 800° C. to 1000° C. A deposition rate is more than 0.1 μm per hour. As soon as the diamond layer 8 has reached a predetermined thickness in the range of 1 to 10 μm, the concentration of the carbonaceous gas based on the total gas composition is increased by at least 1%, preferably at least 1.5%. For example, a methane concentration of 4.5 to 5.5% is adjusted for a dwell time of 60 to 180 seconds. An extremely fine-grained diamond crystal with an average crystal size of 2 to 50 nm is formed thereby, which form an underside of the next following diamond layer. Then the concentration of the carbonaceous gas is again reduced to the first concentration. A first concentration of methane is thus again set at 3.0 to 4.3%, preferably 4.3 to 4.0%. The diamond crystals deposited thereby have a second average crystal size in the region of 50 to 500 nm. A thickness of the further diamond layer deposited under these conditions is in turn 1 to 10 μm. In this manner a plurality of diamond layers stacked one on top of the other can be deposited, which respectively have on their underside a first average crystal size of 2 to 50 nm, wherein the average crystal size increases towards the top side of each diamond layer and there has a second average crystal size in the range of 50 to 500 nm. Preferably, a second average crystal size on the surface is only 150 to 250 nm. In this manner 10 to 30 diamond layers lying one on top of the other can be deposited, so that a total layer thickness of 20 to 200 μm, preferably 40 to 100 μm, is achieved.

Subsequently, the substrate 1 is cooled to ambient temperature. The diamond films 4 formed on both sides of the substrate 1 are detached. They can be cut e.g., by means of a Nd:YAG laser in predetermined geometric shapes (FIG. 1e). For example, the rectangular film sections 5 shown in FIGS. 1e and 1f can be produced, which subsequently can be adhered to a component 6, e.g., by means of a polymer (FIG. 1f).

FIG. 2 shows a diamond film 4, which has been cut into the shape of a toothed wheel by means of a Nd:YAG laser.

FIG. 3 shows a diagrammatic cross-sectional view through the component according to FIG. 1f. The film section 5 is applied onto the component 6 by means of a polymer adhesive layer 7. Instead of the polymer adhesive layer 7, a solder or the like can also be used. Furthermore, for connecting to a metallic substrate it is possible to provide the diamond film 4 with a metal layer on its one side, e.g., by means of sputtering. This metal layer can then be connected to the metallic substrate, for example, by means of ultrasonic welding. It is also possible to connect the diamond film 4 according to the invention directly by means of diffusion welding, for example, to a metallic substrate, in particular aluminum or a further diamond film according to the invention.

FIG. 4 shows that side of a self-supporting diamond film that has been facing towards the hot wires 3 during the hot wire CVD process. It is discernible that here a top side of the diamond film is formed of'diamond crystals, the average crystal size of which is in the range of 100 to 400 nm.

FIG. 5 shows the underside of a self-supporting diamond film, which has been facing away from the hot wires 3 during the hot wire CVD process. This is therefore the contact side to the substrate 1. This side of the diamond film 4 forms essentially the morphology of the substrate 1, i.e., the crystal boundaries of the substrate 1 are formed there.

FIG. 6 shows an electron microscope image of the layer structure of the self-supporting diamond film. A plurality of diamond layers 8 is stacked on the substrate 1, which can be a silicon wafer, for example. The diamond layers 8 have a thickness in the range of 1 to 7 μm. A total layer thickness of all diamond layers 8 is here approximately 50 μm.

FIGS. 7 and 8 shows Raman spectra of a self-supporting diamond film 4. The Raman spectra have been recorded using an argon ion laser with a wavelength of 514.5 nm.

FIG. 7 shows a Raman spectrum of an underside of the first diamond layer 8, which has been produced using the diamond nuclei 2 applied on the substrate 1. The spectrum shows essentially 2 intensity maximums at approximately 1358 cm⁻¹ and 1550 cm⁻¹.

FIG. 8 shows a Raman spectrum, which has been recorded on the uppermost top side of the diamond layers 8. In addition to the above-mentioned intensity maximums, here further intensity maximums in particular at 1135 cm⁻¹, 1332 cm⁻² and 1475 cm⁻¹ are discernible.

### LIST OF REFERENCE NUMBERS

1 Substrate
2 Diamond nucleus
3 Hot wire
4 Diamond film
5 Film section
6 Component
7 Polymer adhesive layer
8 Diamond layer
R_{z} Peak-to-valley height

1-24. (canceled)

25. Self-supporting CVD diamond film, comprising a plurality of diamond layers (8) stacked one on top of the other, wherein an underside of each diamond layer (8) is formed from diamond with a first average crystal size of 2 to 50 nm, wherein the average crystal size inside the diamond layer (8) increases from the underside to a top side of the diamond layer (8) and wherein a second average crystal size in the region of the top side is 50 to 500 nm.

26. Self-supporting CVD diamond film according to claim 25, wherein the first average crystal size is 2 to 30 nm, preferably 5 to 20 nm.

27. Self-supporting CVD diamond film according to claim 25, wherein the second average crystal size is no more than 200 nm.

28. Self-supporting CVD diamond film according to claim 25, wherein at least one diamond layer (8) is provided with an n-doping.

29. Self-supporting CVD diamond film according to claim 25, wherein at least one diamond layer (8) is provided with a p-doping.

30. Self-supporting CVD diamond film according to claim 25, wherein all of the diamond layers are provided with an n-doping or a p-doping.

31. Component in which a self-supporting diamond film (4) according to claim 25 is applied to at least one component surface.

32. Component according to claim 31, wherein the diamond film (4) is applied on the component surface by means of a connecting layer (7).

33. Component according to claim 31, wherein the component surface is a further outside of a further self-supporting CVD diamond film according to one of claims 1 through 6.

34. Thermoelectric component in which p- and n-conducting self supporting CVD diamond films according to claim 28 are connected to one another.

35. Thermoelectric component of claim 34, wherein the self-supporting CVD diamond films are connected with the interposition of a carbide-forming metal layer.

36. Method for producing a self-supporting CVD diamond film (4) according to claim 25 with the following steps:
Application of diamond nuclei (2) onto the surface of a substrate (1),
Insertion of the substrate (1) provided with the diamond nuclei 92) into a reaction chamber of a CVD device,
Deposition of a diamond layer (8) by means of a CVD method, wherein during a first dwell time of 1 to 10 hours in the reaction chamber a predetermined first concentration of a carbonaceous gas is adjusted,
characterized in that to produce at least one further diamond layer (8), the following steps are carried out in succession:
a) Increase of the concentration of the carbonaceous gas to a predetermined second concentration for a second dwell time of 20 to 600 seconds and
b) Reduction of the concentration of the carbonaceous gas to the predetermined first concentration and maintenance of the first concentration for the first dwell time.

37. Method according to claim 36, wherein the steps lit. a) and b) are repeated several times.

38. Method according to claim 36, wherein the first dwell time is 1.5 to 4 hours.

39. Method according to claim 36, wherein the first concentration is 2.8 to 4.0%, preferably 3.0 to 3.8%.

40. Method according to claim 36, wherein the temperature of the substrate (1) is 600° C. to 1,000° C.

41. Method according to claim 36, wherein as a substrate a substrate of copper, molybdenum, tungsten or silicon, preferably a silicon wafer is used.

42. Method according to claims 36, wherein the self-supporting diamond film is exposed to a heat treatment at a temperature of at least 500° C. in an oxygen-containing atmosphere.
